(19) United States
(12) Patent Application Publication
(10) Pub. No.: US 2009/0195979 A1
(43) Pub. Date: Aug. 6, 2009

(54) Electronic device with fans

(75) Inventors: Ping Ji, Shanhai City (CN); Chih-Feng Chen, Taipei City (TW)

Correspondence Address: Edwards Angell Palmer & Dodge LLP, P.O.Box 55874, Boston, MA, 02205, US

(73) Assignee: Inventec Corporation, Taipei City (TW)

(21) Appl. No.: 12/151,082

(22) Filed: May 2, 2008

(30) Foreign Application Priority Data
Feb. 5, 2008 (TW) 097104498

(51) Int. Cl. G06F 1/20; H05K 7/20

(52) U.S. Cl. 361/679.48

(57) ABSTRACT

An electronic device with fans is provided according to the present invention. The electronic device with fans includes an opening on a lid body of electronic housing, wherein one or more engaging portions are disposed on the rim of the opening, and the fans are engaged with a shield panel. While the fans are installed in the electronic device via the opening, the rim of the shield panel is engaged with the engaging portions to seal the opening. While maintaining, testing or replacing the fans, the fans are removed from the electronic housing by taking off the shield panel without opening the lid body.

### BACKGROUND OF THE INVENTION

1. Field of the Invention

This invention generally relates to an electronic device with fans, and more particularly, to an electronic device that is a server and includes fans.

2. Description of Related Art

With rapid blooming of Internet, Internet surfing is taking an influential role in the way we do our daily business. In order to conveniently create internal connections among mainframes at various locations of a company for providing message communications and data transmissions, electronic devices such as servers have become very essential devices. Also, for being always at high performance, interior maintenances, tests, and replacements of a server should be well controlled.

Hot plugging is used as the connection mode of internal members, such as hard disk modules, power supply devices, fan modules, etc. for maintenance, test, and replacement of a server, as disclosed in Taiwan Patent Nos. 555040, 472917, 1266580, and 268134, etc.

Please refer to FIG. 1, which is a schematic view showing a conventional server including fans. As shown in FIG. 1, the server 1 includes an electronic housing 10, a fan module 11, and a mainframe unit including a motherboard 12, a hard disk module 13, and power supply device (not shown in FIG. 1). The electronic housing 10 includes a casing 10a and an upper lid 10b that is engaged with the casing 10a. The fan module 11 has a fan housing 111 and a plurality of fans 110 that are positioned inside the fan housing 111. Also, the fan module 11, the motherboard 12, the hard disk module 13, and the power supply device are all disposed inside the electronic housing 10. The fan module 11 can be electrically connected to the motherboard 12. Alternatively, a small-scale circuit board (not shown) is disposed under the fan module 11, and the fan module 11 is electrically connected to the motherboard 12 via the circuit board.

Since the fan module 11 is fixed inside of the electronic housing 10, at the time of maintenance, test, or replacement of the fan module 11, the upper lid 10b of the electronic housing 10 must be disassembled before removing the fan module 11.

However, the fan module 11 of the server 1 includes a plurality of fans 110 integrated all together. The upper lid 10b has to be taken off before removing the fan module 11, and it not only consumes time, but also stops operation of the server 1, thereby leading to system instability or service interruption. Furthermore, it might cause inestimable loss in profits. In other words, at the time that the fan module 11 of the server 1 has to be maintained, tested, or replaced, the conventional procedure is complicated, inconvenient and increasing cost.

Hence, it is a highly urgent issue in the industry to provide a technique for effectively eliminating the drawbacks in the conventional electronic devices using the hot plugging mode of a fan module.

### SUMMARY OF THE INVENTION

In view of the disadvantages of the prior art mentioned above, it is a primary objective of the present invention to provide an electronic device with fans for facilitating the disassembly of the fans.

It is another objective of the present invention to provide a reliable electronic device with fans.

It is a further objective of the present invention to provide an electronic device with fans for enhancing system stability.

To achieve the aforementioned and other objectives, an electronic device with fans is provided according to the present invention. The electronic device with fans includes an electronic housing, a mainframe unit and a fan module that are disposed in the electronic housing. The electronic housing includes a casing and a lid body engaged with the casing, and the lid body has at least an opening and an engaging portion that is disposed around the opening. The mainframe unit has a motherboard. The fan module includes a shield panel corresponding to the opening and fans that are engaged with the bottom surface of the shield panel. The shield panel is engaged with the engaging portion to close the opening, and the fans are electrically connected to the motherboard in the electronic housing.

The electronic device with fans can be one of server, personal computer, laptop computer, portable electronic device, etc. In one embodiment, the electronic device includes a hard disk module electrically connected to the motherboard, the fan module further includes a plurality of first connectors electrically connected to the fans, and the motherboard includes a plurality of second connectors electrically connected to the first connectors.

Preferably, the size of the fans is smaller than the size of the opening, and the fans are contained in a frame, and the shield panel is mounted on top of the frame. The size of the shield panel is larger than the size of the opening, wherein the shield panel can be selectively glued and fixed to the frame, or screwed and fixed to the frame. In addition, the engaging portion can be step-like for being engaged with the rim of the shield panel. In one embodiment, the engaging portion and the shield panel are formed with corresponding threaded holes, and the electronic device includes screws corresponding to the threaded holes, so that the shield panel is fastened to the lid body.

In addition, the electronic device with fans of the present invention can further include protection portions disposed in the casing for protecting the fans. Alternatively, the protection portion can be disposed on the shield panel. In the present invention, the protection portion is disposed on a lateral side of the fans. Preferably, the protection portion can be a grid.

In view of the above, the lid body is formed with an opening, the fans are mounted on the shield panel that is corresponding to the opening in size, and the fans can be removed along with the shield panel. Therefore, the fans can be pulled out from the electronic housing by removing the shield panel, so as to facilitate the maintenance, test and replacement of the fans. In comparison with the prior art, the fan maintenance, test and replacement of fans can be performed without turning off power of the electronic device and opening the lid body of the electronic housing. Moreover, the present invention provides a reliable electronic device with fans for effectively enhancing system stability.

### BRIEF DESCRIPTION OF DRAWINGS

The present invention can be more fully understood by reading the following detailed description of the preferred embodiments, with reference made to the accompanying drawings, in which

FIG. 1 is a schematic view showing a conventional server having fans;

FIG. 2 is a schematic view showing the electronic device with fans according to the first embodiment of the present invention;

FIG. 3A and 3B are sectional views showing the electronic device with fans of FIG. 2;

FIG. 4A is a schematic view showing a portion of the electronic device with fans according to the second embodiment of the present invention;

FIG. 4B is a schematic view showing a portion of the electronic device with fans according to the third embodiment of the present invention;

FIG. 4C is a schematic view showing a portion of the electronic device with fans according to the fourth embodiment of the present invention; and

FIG. 5 is a schematic view showing the electronic device with fans according to the fifth embodiment of the present invention.

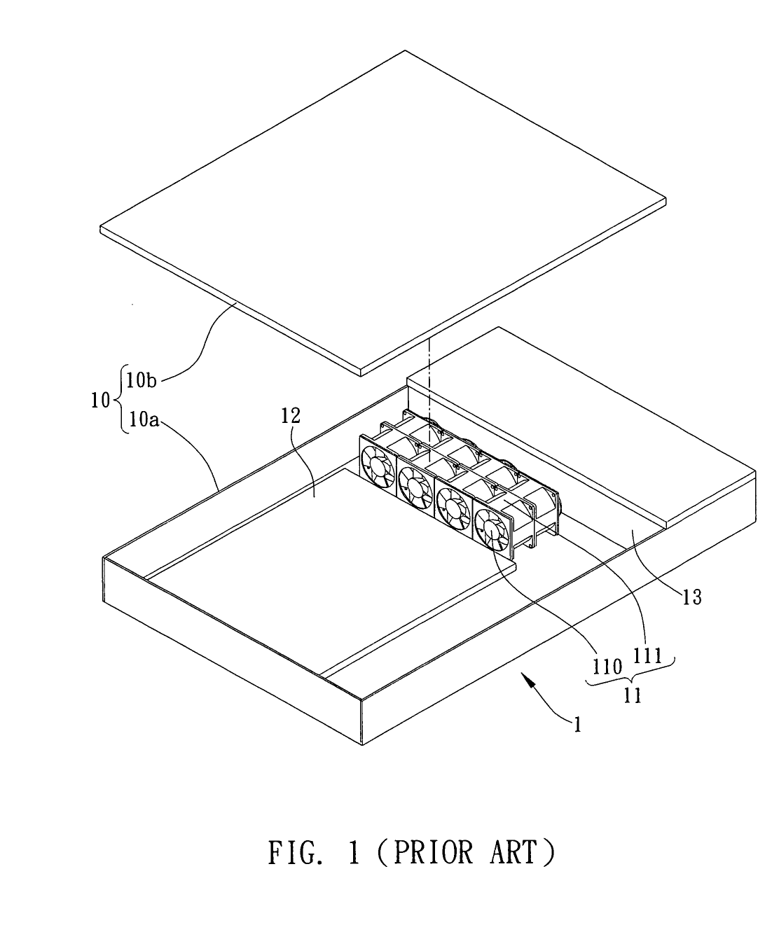

### DETAILED DESCRIPTION OF PREFERRED EMBODIMENTS

The following illustrative embodiments are provided to illustrate the disclosure of the present invention. Persons skilled in the art can understand the advantages and effects of the present invention after reading the disclosure of this specification. The present invention can also be performed or applied by other different embodiments. The details of the specification may be on the basis of different points and applications, and numerous modifications and variations can be devised without departing from the spirit of the present invention.

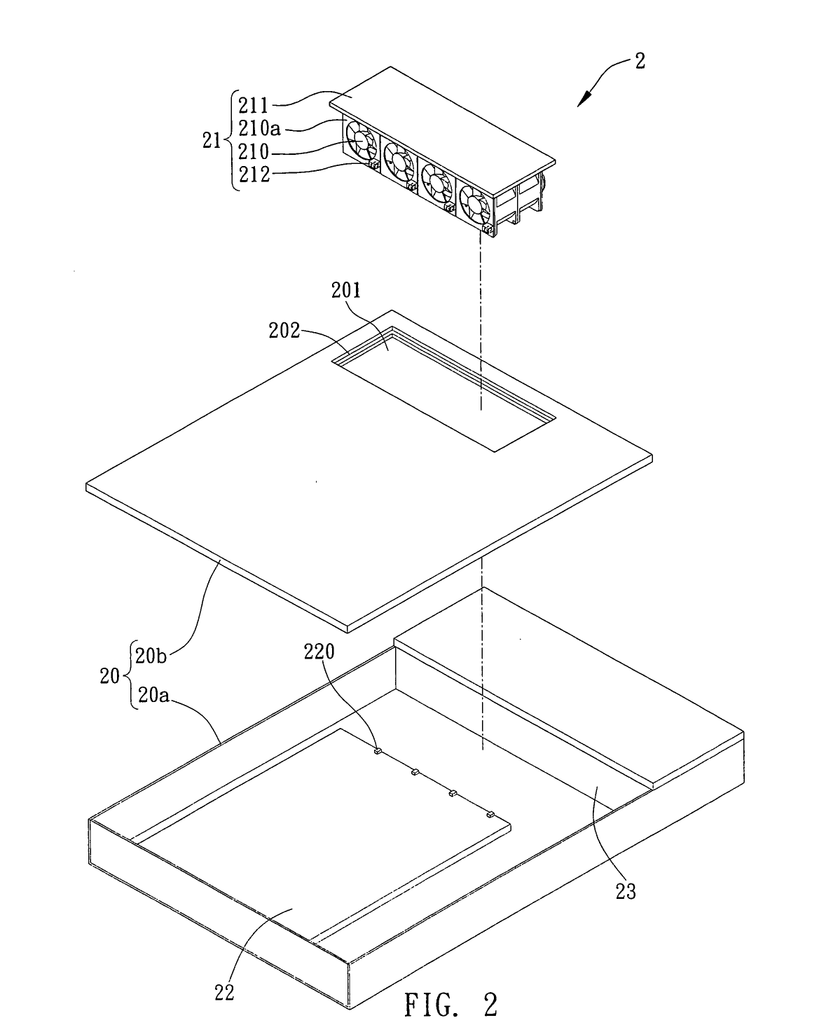

Please refer to FIG. 2, which is a schematic view showing the electronic device with fans according to the first embodiment of the present invention. The electronic device with fans of the present invention can be, but not limited to a server and any other electronic devices that require fan maintenance, test, and replacement, for instance, personal computers, laptop computers, portable electronic devices, etc. As shown in FIG. 2, the electronic device 2 includes an electronic housing 20, a fan module 21 and a mainframe unit wherein the fan module 21 and the mainframe unit are disposed in the electronic housing 20.

For example, the electronic device 2 is a server. The mainframe unit includes a motherboard 22, a hard disk module 23 that is electrically connected to the motherboard 22, and a power supply device (not shown in FIG. 2). The motherboard 22, the hard disk module 23 and the power supply device are all disposed in the electronic housing 20. Certainly, there can be other electronic components disposed in the mainframe unit. Since server and its related parts are well understood by those in the art, the descriptions here are only for the features of the present embodiment.

The electronic housing 20 has a casing 20a and a lid body 20b engaged with the casing 20a, the lid body 20b has at least an opening 201, and an engaging portion 202 is formed on the lid body 20b corresponding to the rim of the opening 201. In the present embodiment, the engaging portion 202 is step-like for being engaged with the fan module 21.

The fan module 21 has at least one fan 210, a shield panel 211 for the fan 210 to be connected thereto, and a first connector 212 for being electrically connected to the fan 210. In the present embodiment, the fans 210 are disposed in a frame 210a and are electrically connected to the motherboard 22 in the electronic housing 20. Also, the size of the fans 210 is smaller than the size of the opening 201, and the frame 210a is integrated to the bottom surface of the shield panel 211. In other embodiments, the frame 210a can be omitted, and the fans 210 can be integrated directly to the bottom surface of the shield panel 211. The shield panel 211 is disposed on top of the frame 210a and corresponding to the opening 201 of the lid body 20b. In the present embodiment, the size of the shield panel 211 is larger than the size of the opening 201, and the rim of the shield panel 211 is engaged with the engaging portion 202 so as to seal the opening 201, thereby allowing the fans 210, the frame 210a and the first connectors 212 to be disposed in the electronic housing 20.

It should be noted that the shield panel 211 is glued and fixed to the frame 210a in the present embodiment, but in other embodiments, the shield panel 211 can be screwed and fixed to the frame 210a, thereby fastening the shield panel 211 to the frame 210a.

The motherboard 22 includes second connectors 220 for being electrically connected to the first connectors 212, thereby allowing the fan module 21 to be electrically connected to the motherboard 22.

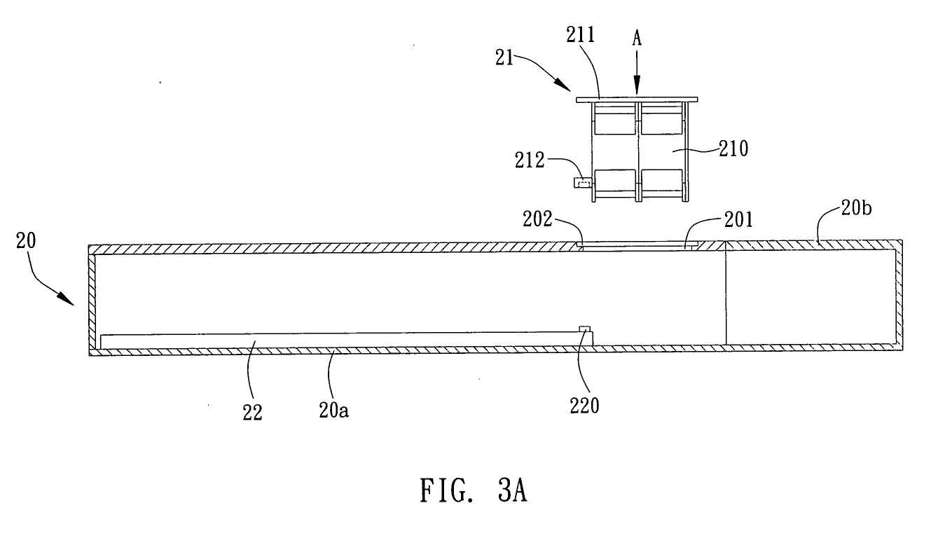

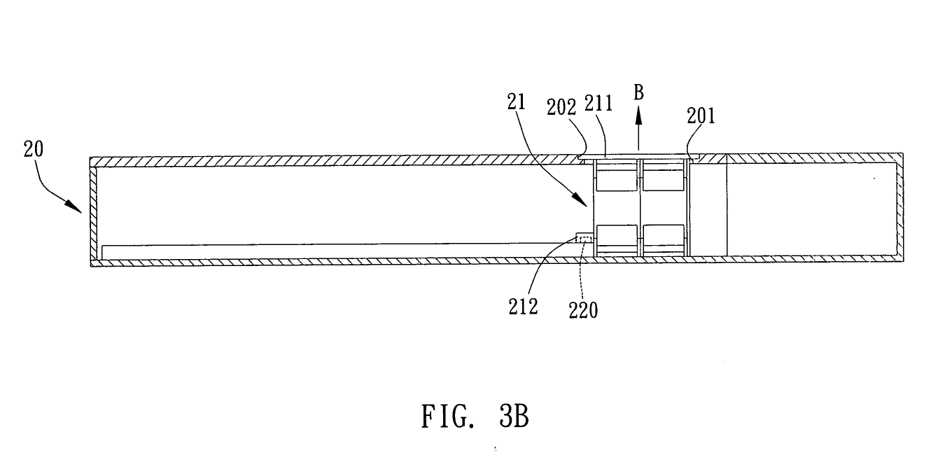

Please refer to FIGS. 3A and 3B, which are schematic views showing the assembly of the electronic device 2 with fans of the present invention. As shown in FIG. 3A, when the fan module 21 is assembled to the electronic housing 20, the fans 210 of the fan module 21 are placed into the casing 20a through the opening 201 in the direction indicated by arrow A, and then the first connectors 212 of the fan module 21 are plugged into the second connectors 220 of the motherboard 22 for electrically connecting the fans 210 to the motherboard 22. The shield panel 211 of the fan module 21 is engaged with step-like engaging portion 202, thereby fixing the fan module 21 to the lid body 20b of the electronic housing 20. Thus, the opening 201 of the lid body 20b is sealed by the shield panel 211 as shown in FIG. 3B.

According to the present invention, when the fan module 21 requires a maintenance, repair or replacement, only the shield panel 211 is taken off in the direction as indicated by arrow B, thereby enabling the first connectors 212 to be separated from the second connectors 220. Subsequently, the shield panel 211 is disengaged from the engaging portion 202 and removed from the opening 201. Thus, the fan module 21 is removed from the electronic housing 20 so as to be maintained, tested or replaced. Therefore, in comparison with the prior art, the electronic device with fans provided by the present invention is conveniently maintained, tested and replaced without being shut down and opening the lid body 20b.

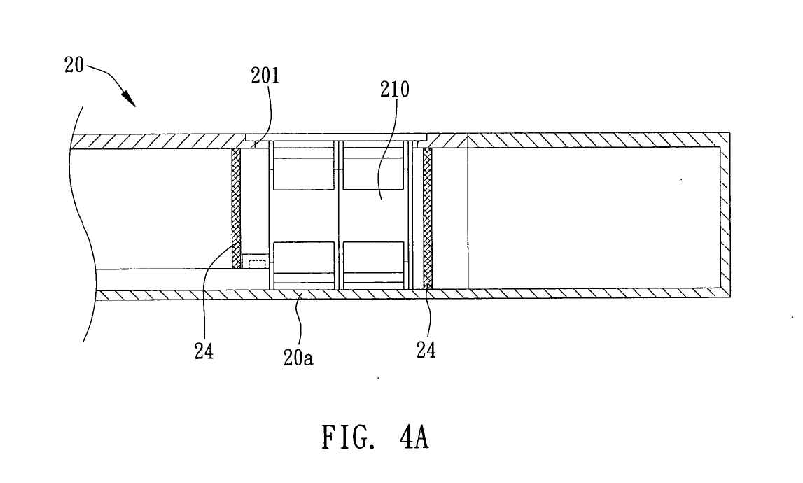

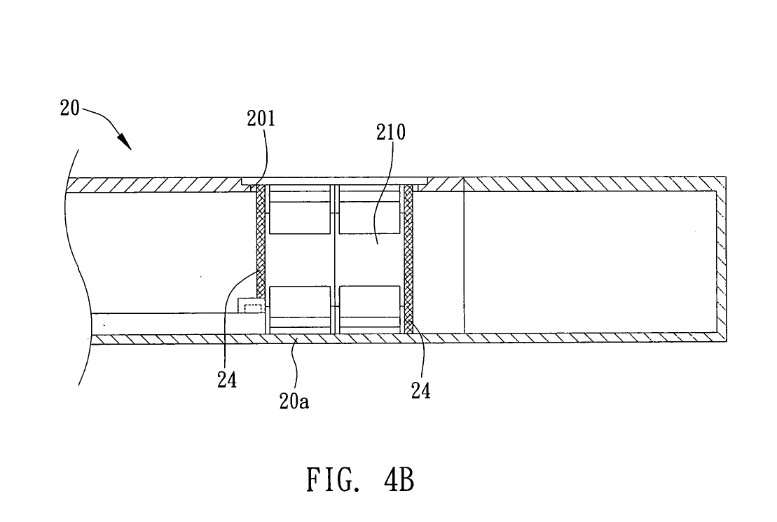

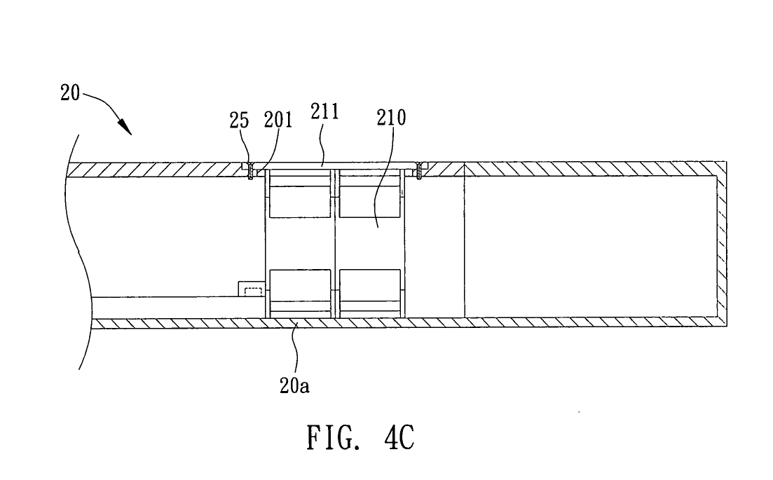

The president invention also provides many variations. Please refer to FIG. 4A, which is a schematic view showing the electronic device with fans according to the second embodiment of the present invention, and elements of the present embodiment same as those in the first embodiment are illustrated with same reference numerals. In the second embodiment, the electronic device 2 with fans further includes at least one protection portion 24. The protection portion 24 can be a grid 24 disposed on the lateral side of the fans 210 in the casing 20a for protecting fans 210 in the electronic housing 20. In the present embodiment, the protection portions 24 are disposed on both lateral sides of the fans 210 for preventing the fans 210 from being attached by dust, floating particles or impurities. However, in other embodiments, the protection portion 24 can, but not limited to be disposed on at least one lateral side (such as ventilator side) of the fans 210.

Furthermore, FIG. 4B is a schematic view showing the electronic device with fans according to the third embodiment of the present invention. The protection portion 24 of the third embodiment is disposed on the shield panel 211, and the protection portion 24 is disposed vertically to the shield panel 211 and disposed on the lateral side of the fans 210 for protecting the fans 210. Similarly, one or two protection portions 24 can be disposed on the shield panel 211 for protecting the fans 210.

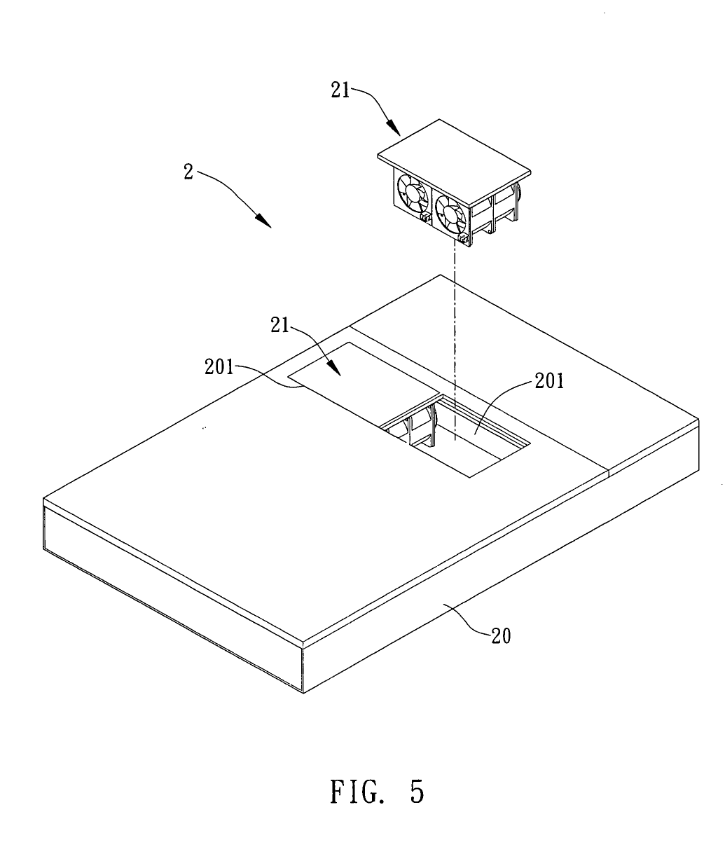

In addition, FIG. 4C is a schematic view showing the electronic device with fans according to the fourth embodiment of the present invention. The shield panel 211 of the fourth embodiment is screwed and fixed to the lid body 20b. In the fourth embodiment, both the engaging portion 202 and the shield panel 211 have corresponding threaded holes (not shown), and the electronic device includes screws 25 corresponding to the threaded holes, thereby fastening the shield panel to the lid body 20b by means of the screws. Therefore, while moving the electronic device, the fans 210 are prevented from being shifted or separated from the electronic housing 20. Please refer to FIG. 5, which is a schematic view showing the electronic device with fans according to the fifth embodiment of the present invention. In the fifth embodiment, two openings 201 are formed for receiving two fan modules 21 in the electronic housing 20 respectively. In this embodiment, only the fan module, which requires maintenance, test or replacement, is removed from the electronic housing. Also, in other embodiments, two fan modules can be disposed in one opening 201 of the electronic housing 20. In other words, the number of openings and number of fan modules 21 may not be equal. In addition, although the fan module 21 consists of eight fans according to the embodiments of the present invention, the number of fans in the fan module 21 is not limited in the present invention. The shield panel 211 can be engaged with one fan 210, eight fans 210 or four fans 210.

In summary, in the electronic device with fans of the present invention, the electronic housing is formed with an opening on the lid body of electronic housing, and the fans are disposed on the shield panel that is used for correspondingly sealing the opening, thereby allowing the fans to be removed along with the shield panel. In other words, the fans are removed from the electronic housing by taking off the shield panel for maintenance, test and replacement of the fans. In addition, since fans can be maintained, tested, or replaced without shutting down the electronic device and opening lid body of electronic housing, the present invention provides a simple, convenient, reliable means to enhance system stability.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. An electronic device with fans, comprising:
an electronic housing having a casing and a lid body engaged with the casing, wherein the lid body has at least an opening and an engaging portion disposed around the opening;
a mainframe unit disposed in the electronic housing and having a motherboard; and
at least a fan module having a shield panel corresponding to the opening, and having fans disposed under a bottom surface of the shield panel, wherein the shield panel is engaged with the engaging portion for closing the opening, and the fans are electrically connected to the motherboard disposed in the electronic housing.

2. The electronic device with fans of claim 1, further comprising a frame for the fans to be disposed therein, wherein the shield panel is mounted on the frame.

3. The electronic device with fans of claim 2, wherein the shield panel is glued and fixed to the frame.

4. The electronic device with fans of claim 1, wherein the fan module comprises first connectors electrically connected to the fans, and the motherboard comprises second connectors electrically connected to the first connectors.

5. The electronic device with fans of claim 1, wherein the engaging portion is step-like and is for being engaged with rim of the shield panel.

6. The electronic device with fans of claim 1, wherein the engaging portion and the shield panel are formed with corresponding threaded holes respectively, and the electronic device further comprises screws corresponding to the threaded holes, allowing the shield panel to be fastened to the lid body.

7. The electronic device with fans of claim 1, wherein total size of the fans is smaller than the size of the opening.

8. The electronic device with fans of claim 1, wherein the size of the shield panel is larger than the size of the opening.

9. The electronic device with fans of claim 1, further comprising a protection portion in the casing for protecting the fans.

10. The electronic device with fans of claim 9, wherein the protection portion is a grid.

11. The electronic device with fans of claim 1, further comprising a protection portion in the shield panel, and the protection portion is disposed on a lateral side of the fans for protecting the fans.

12. The electronic device with fans of claim 11, wherein the protection portion is a grid.
